(19) United States
(12) Patent Application Publication
(10) Pub. No.: US 2026/0271181 A1
(43) Pub. Date: Sep. 10, 2026

(54) CIRCUIT MODULE, CIRCUIT BOARD, ELECTRONIC DEVICE, AND PACKAGE MODULE

(71) Applicant: LITE-ON TECHNOLOGY CORPORATION, TAIPEI CITY (TW)

(72) Inventors: Kai-Chieh Chiang, TAIPEI CITY (TW); CHIA-YUN LEE, New Taipei City (TW); Po-Chieh Huang, TAIPEI CITY (TW)

(21) Appl. No.: 19/557,060

(22) Filed: Mar. 4, 2026

Related U.S. Application Data
(60) Provisional application No. 63/768,179, filed on Mar. 7, 2025.

(30) Foreign Application Priority Data
Jan. 27, 2026 (CN) 202620109587.8

(51) Int. Cl. H05K 1/02; H05K 1/181

(52) U.S. Cl. CPC H05K 1/0256; H05K 1/0296; H05K 1/181; H05K 2201/09063; H05K 2201/10303; H05K 2201/10977

(57) ABSTRACT

A circuit module, a circuit board, an electronic device, and a package module. The circuit board includes two first metal pads and two second metal pads respectively corresponding to the two first metal pads. Each of the first metal pads and a corresponding one of the second metal pads jointly define a first initial creepage path therebetween, and the two second metal pads jointly define a second initial creepage path therebetween. The circuit board has a first penetrating groove and a second penetrating groove that is arranged between the two second metal pads. Each of the first metal pads and the corresponding second metal pad are spaced apart from each other by the first penetrating groove to jointly define a first extension creepage path. The two second metal pads are spaced apart from each other by the second penetrating groove to jointly define a second extension creepage path.

### CROSS-REFERENCE TO RELATED PATIENT APPLICATION

This application claims the benefit of priority to China Patent Application No. 202620109587.8, filed on Jan. 27, 2026, in the People’s Republic of China. The entire content of the above identified application is incorporated herein by reference.

This application claims the benefit of priority to the U.S. Provisional Patent Application Ser. No. 63/768,179, filed on Mar. 7, 2025, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a structure for an electronic component, and more particularly to a circuit module, a circuit board, an electronic device, and a package module.

### BACKGROUND OF THE DISCLOSURE

A conventional electronic device has a challenge of increasing voltage withstand requirements and creepage distance requirements, but there are limitations to the size of conventional electronic devices, making it increasingly difficult to meet future market requirements.

### SUMMARY OF THE DISCLOSURE

In response to the above-referenced technical inadequacies, the present disclosure provides a circuit module, a circuit board, an electronic device, and a package module for effectively improving on the issues associated with conventional electronic devices.

In order to solve the above-mentioned problems, one of the technical aspects adopted by the present disclosure is to provide a circuit module in which the creepage distance between input and output terminals is effectively increased by structural arrangements formed on a circuit board. The circuit module includes two first metal pads and two second metal pads disposed on opposite sides of the circuit board. A first penetrating groove passes through two first initial creepage paths respectively defined between each first metal pad and its corresponding second metal pad. A second penetrating groove is arranged between the two second metal pads and passes through a second initial creepage path defined therebetween.

By providing groove ends at both penetrating grooves, each first metal pad and its corresponding second metal pad jointly define a first extension creepage path adjacent to a first groove end, having a length falling within 110%–500% of the first initial creepage path. Likewise, the two second metal pads define a second extension creepage path adjacent to a second groove end, falling within 130%–500% of the second initial creepage path.

Through these groove structures, electric field paths originally following shortest straight-line creepage routes are interrupted, forcing creepage to extend around the groove ends, thereby achieving significantly increased creepage distance within limited board area.

Therefore, the circuit module, the circuit board, the electronic device, and the package module in the present disclosure can be provided by forming the first penetrating groove and the second penetrating groove at specific positions on the circuit board for enabling the first initial creepage path to be effectively extended to the first extension creepage path, and the second initial creepage path to be effectively extended to the second extension creepage path, so that the circuit board (or the electronic device) can meet more stringent creepage distance requirements.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of an electronic device according to a first embodiment of the present disclosure;

FIG. 2 is a schematic perspective view showing the electronic device of FIG. 1 when an encapsulant is omitted;

FIG. 3 is a schematic exploded view of FIG. 2;

FIG. 4 is a schematic top view of FIG. 2;

FIG. 5 is a schematic top view of FIG. 2 when a second penetrating groove of the electronic device is in another configuration;

FIG. 6 is a schematic top view of FIG. 2 when the second penetrating groove is in yet another configuration;

FIG. 7 is a schematic cross-sectional view taken along line VII-VII of FIG. 1;

FIG. 8 is a schematic exploded view of FIG. 2 when a positioning structure of the electronic device is in another configuration;

FIG. 9 is a schematic cross-sectional view showing the electronic device in another configuration;

FIG. 10 is a schematic perspective view of the electronic device provided with two electronic components;

FIG. 11 is a schematic cross-sectional view of the electronic device according to a second embodiment of the present disclosure;

FIG. 12 is a schematic cross-sectional view of the electronic device in another configuration; and

FIG. 13 is a schematic cross-sectional view of the electronic device in yet another configuration.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

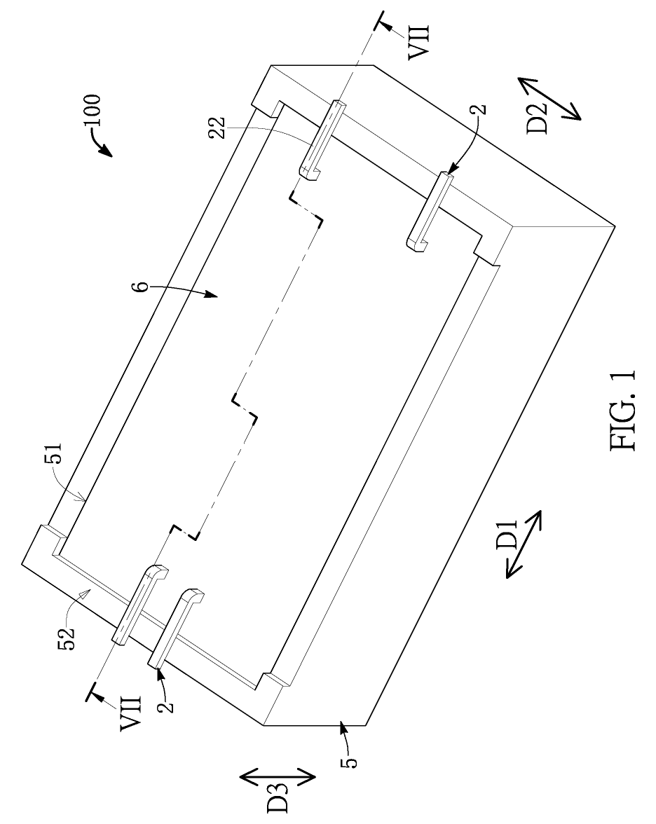

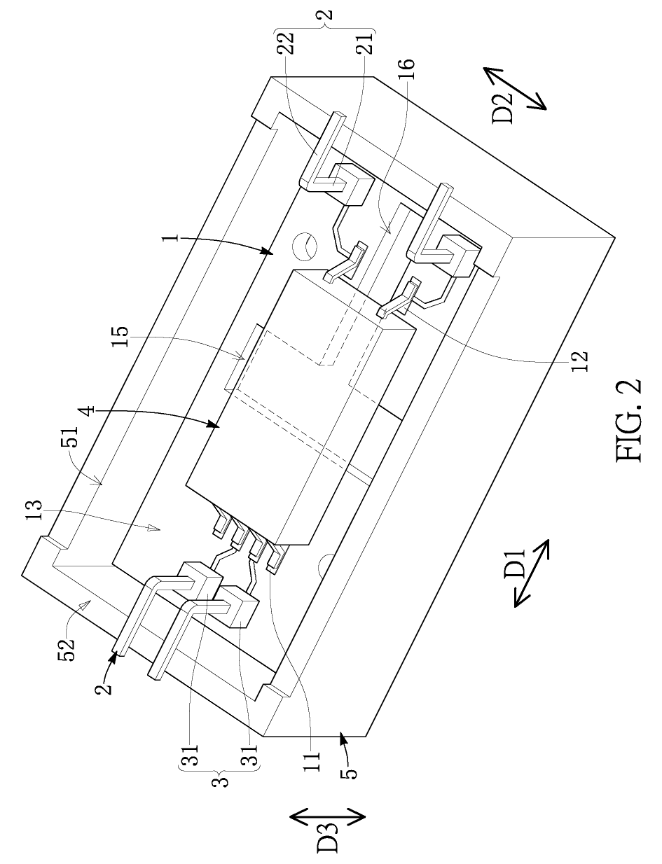

Referring to FIGS. 1 to 10, a first embodiment of the present disclosure is provided. As shown in FIGS. 1 to 3, the present embodiment provides an electronic device 100, which can be used as a relay, but the present disclosure is not limited thereto. In the present embodiment, the electronic device 100 includes a circuit board 1, a plurality of pins 2 fixed to the circuit board 1, a positioning structure 3 assembled to the pins, an electronic component 4 disposed on the circuit board 1, a case 5 accommodating the above-mentioned components, and an encapsulant 6 that is filled in the case 5. The electronic component 4 in the present embodiment is an optocoupler, but the present disclosure is not limited thereto. For example, in other embodiments of the present disclosure not shown in the drawings, the positioning structure 3 can be omitted or replaced with other components according to practical requirements; or the electronic component 4 can adopt components other than the optocoupler.

It should be noted that the circuit board 1 and the pins 2 can jointly define a circuit module, and the circuit module can be further provided with the positioning structure 3 according to practical requirements. Furthermore, the case 5, the electronic component 4, the pins 2, and the encapsulant 6 can also jointly define a package module. In addition, although the electronic device 100 in the present embodiment is illustrated as including the above-mentioned components, the present disclosure is not limited thereto. For example, in other embodiments of the present disclosure not shown in the drawings, any one of the circuit module, the circuit board 1, and the package module can be independently applied (e.g., sold) or can be used in cooperation with other components according to practical requirements.

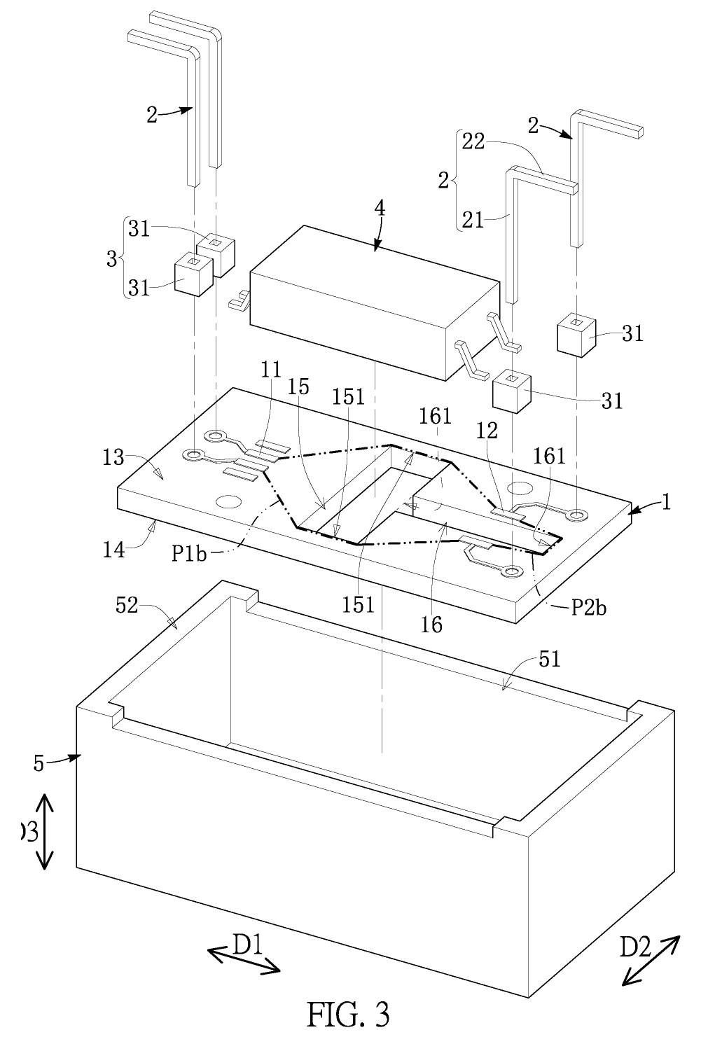

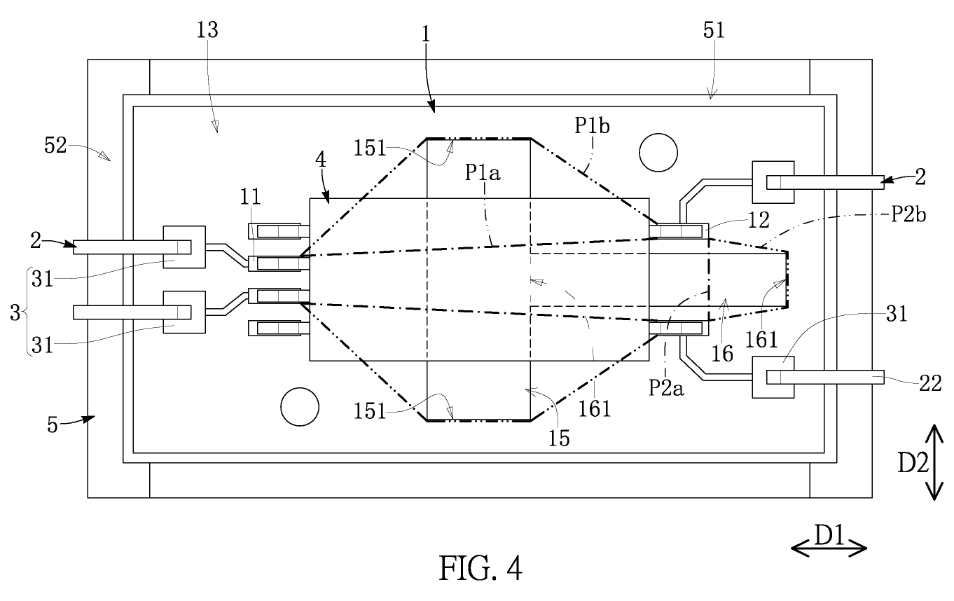

In the present embodiment, as shown in FIGS. 3 and 4, the circuit board 1 includes two first metal pads 11 and two second metal pads 12 that respectively correspond to the two first metal pads 11. The circuit board 1 has a first board surface 13 and a second board surface 14 respectively located on two opposite sides thereof, and the two first metal pads 11 and the two second metal pads 12 in the present embodiment are arranged on the first board surface 13 of the circuit board 1, and the two first metal pads 11 and the two second metal pads 12 are four solder pads respectively and electrically coupled to the pins 2.

Furthermore, the two first metal pads 11 are spaced apart from each other and are disposed on one side of the circuit board 1 (e.g., the left side of the circuit board 1 shown in FIG. 4), and the two second metal pads 12 are spaced apart from each other and are disposed on another side of the circuit board 1 (e.g., the right side of the circuit board 1 shown in FIG. 4). A distance between the two first metal pads 11 in the present embodiment is less than a distance between the two second metal pads 12, but the present disclosure is not limited thereto.

It should be noted that the two first metal pads 11 in the present embodiment are used as input terminals (or control terminals), and the two second metal pads 12 are used as output terminals (or power terminals), so that there are creepage distance requirements between each of the two first metal pads 11 and a corresponding one of the second metal pads 12, and between the two second metal pads 12.

Specifically, each of the two first metal pads 11 and the corresponding one of the two second metal pads 12 jointly define a first initial creepage path P1a therebetween. In other words, a shortest linear path on the first board surface 13 between each of the two first metal pads 11 and the corresponding one of the second metal pads 12 is defined as the first initial creepage path P1a. Furthermore, the two second metal pads 12 jointly define a second initial creepage path P2a therebetween. In other words, a shortest linear path on the first board surface 13 between the two second metal pads 12 is defined as the second initial creepage path P2a.

The circuit board 1 further includes at least one creepage‑distance‑extending structure, which is formed with a first penetrating groove 15 and a second penetrating groove 16, and the specific shapes and arrangement relationship of the first penetrating groove 15 and the second penetrating groove 16 can be adjusted or changed according to practical requirements. The following description describes one of the configurations of the first penetrating groove 15 and the second penetrating groove 16, but the present disclosure is not limited thereto.

The first penetrating groove 15 passes through the two first initial creepage paths P1a, and the two first metal pads 11 are spaced apart from the two second metal pads 12 along a first direction D1 through the first penetrating groove 15. In other words, a portion of each of the first initial creepage paths P1a is arranged in the first penetrating groove 15, so that an electric field defined by any one of the first initial creepage paths P1a is interrupted by the first penetrating groove 15 and cannot travel along any one of the first initial creepage paths P1a.

In the present embodiment, the first direction D1 is parallel to a longitudinal direction of the circuit board 1, and the first penetrating groove 15 has a straight shape and is substantially parallel to a second direction D2 that is perpendicular to the first direction D1, but the present disclosure is not limited thereto. For example, in other embodiments of the present disclosure not shown in the drawings, the first penetrating groove 15 can have an arc shape, a wavy shape, or an irregular shape according to practical requirements.

Specifically, the first penetrating groove 15 in the present embodiment has two first groove ends 151, and each of the two first metal pads 11 and the corresponding one of the second metal pads 12 jointly define a first extension creepage path P1b at an adjacent one of the two first groove ends 151, and a length of the first extension creepage path P1b is within a range from 110% to 500% of the first initial creepage path P1a. In other words, on the first board surface 13, a shortest path passing through each of the two first metal pads 11, the corresponding one of the two second metal pads 12, and the adjacent one of the two first groove ends 151 is defined as the first extension creepage path P1b.

The second penetrating groove 16 is arranged between the two second metal pads 12, and one of the two second metal pads 12 is spaced apart from another one of the two second metal pads 12 along the second direction D2 through the second penetrating groove 16. In other words, a portion of the second initial creepage path P2a is arranged in the second penetrating groove 16, so that an electric field defined by the second initial creepage path P2a is interrupted by the second penetrating groove 16 and cannot travel along the second initial creepage path P2a.

In the present embodiment, the second penetrating groove 16 has a straight shape and is substantially parallel to the first direction D1, and the circuit board 1 is substantially and symmetrically arranged with respect to the second penetrating groove 16, but the present disclosure is not limited thereto. For example, in other embodiments of the present disclosure not shown in the drawings, the second penetrating groove 16 can have an arc shape, a wavy shape, or an irregular shape according to practical requirements; or the circuit board 1 can be arranged in a non-mirror symmetrical arrangement with respect to the second penetrating groove 16.

Specifically, the second penetrating groove 16 in the present embodiment has two second groove ends 161, and the two second metal pads 12 and an adjacent one of the two second groove ends 161 jointly define a second extension creepage path P2b. Moreover, a length of the second extension creepage path P2b is within a range from 130% to 500% of the second initial creepage path P2a. In other words, on the first board surface 13, a shortest path passing through the two second metal pads 12 and the adjacent one of the two second groove ends 161 is defined as the second extension creepage path P2b.

Accordingly, in the present embodiment, through the arrangement of the first penetrating groove 15 and the second penetrating groove 16, the circuit board 1 enables the first initial creepage path P1a to be effectively extended to the first extension creepage path P1b, and the second initial creepage path P2a to be effectively extended to the second extension creepage path P2b, so that the circuit board 1 (or the electronic device 100) can meet more stringent creepage distance requirements.

For example, an edge of the circuit board 1 is spaced apart from any adjacent one of the two first groove ends 151 by a distance of at least 1.5 millimeters, and the edge of the circuit board 1 is also spaced apart from an adjacent one of the two second groove ends 161 by a distance of at least 1.5 millimeters, so that the circuit board 1 can have a predetermined structural strength.

Furthermore, the first penetrating groove 15 has a length of at least 3 millimeters and a width of at least 1.5 millimeters and can correspond to an insulation distance of at least 14.8 millimeters, and the first extension creepage path P1b can be 11.6 millimeters. The second penetrating groove 16 has a length of at least 4 millimeters and a width of at least 2 millimeters and corresponds to an insulation distance of 15.4 millimeters, and the second extension creepage path P2b can be 6 millimeters, but the present disclosure is not limited thereto.

It should be noted that the corresponding relationship between the first penetrating groove 15 and the second penetrating groove 16 can be adjusted or changed according to practical requirements. The following description describes several configurations of the first penetrating groove 15 and the second penetrating groove 16, but the present disclosure is not limited thereto.

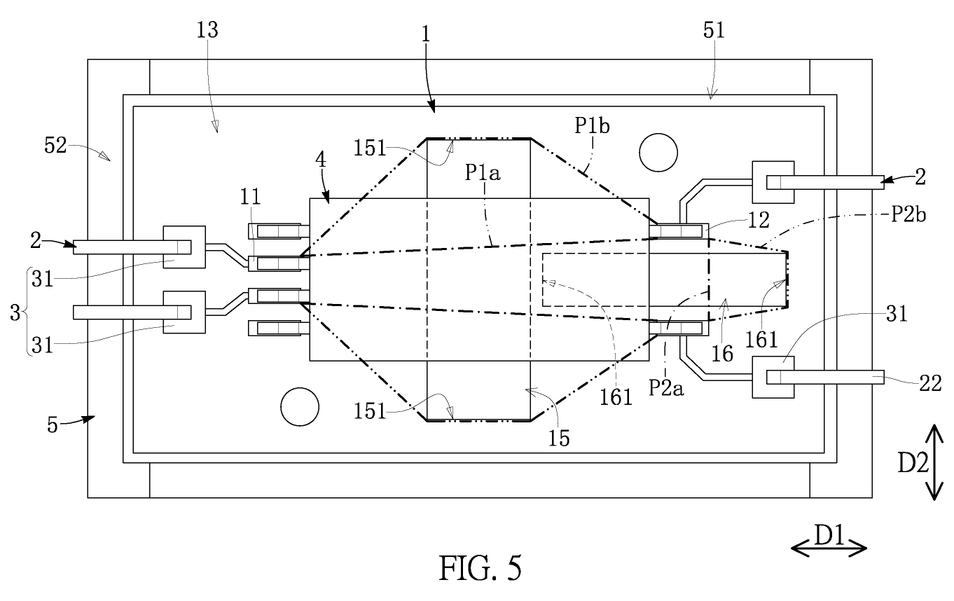

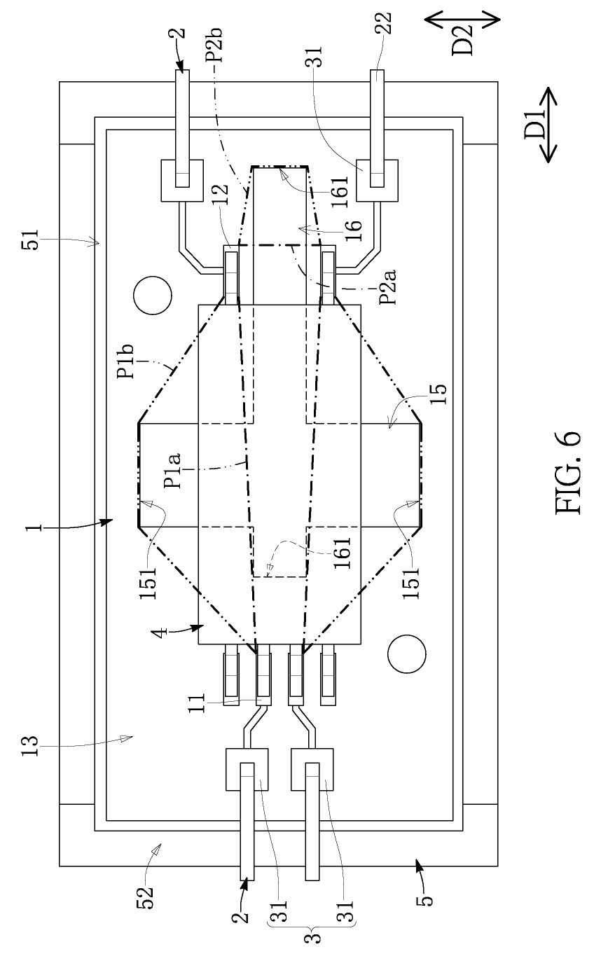

As shown in FIG. 4, one of the two second groove ends 161 of the second penetrating groove 16 (e.g., the second groove end 161 not defining the second extension creepage path P2b) is connected to the first penetrating groove 15. In other words, the first penetrating groove 15 and the second penetrating groove 16 are in spatial communication with each other and jointly form a T-shaped arrangement. Alternatively, as shown in FIG. 5, one of the two second groove ends 161 of the second penetrating groove 16 (e.g., the second groove end 161 not defining the second extension creepage path P2b) is spaced apart from the first penetrating groove 15. Alternatively, as shown in FIG. 6, the second penetrating groove 16 intersects with the first penetrating groove 15, and the two second groove ends 161 are respectively arranged at two opposite sides of the first penetrating groove 15. In other words, the first penetrating groove 15 and the second penetrating groove 16 are in spatial communication with each other and jointly form a cross-shaped arrangement.

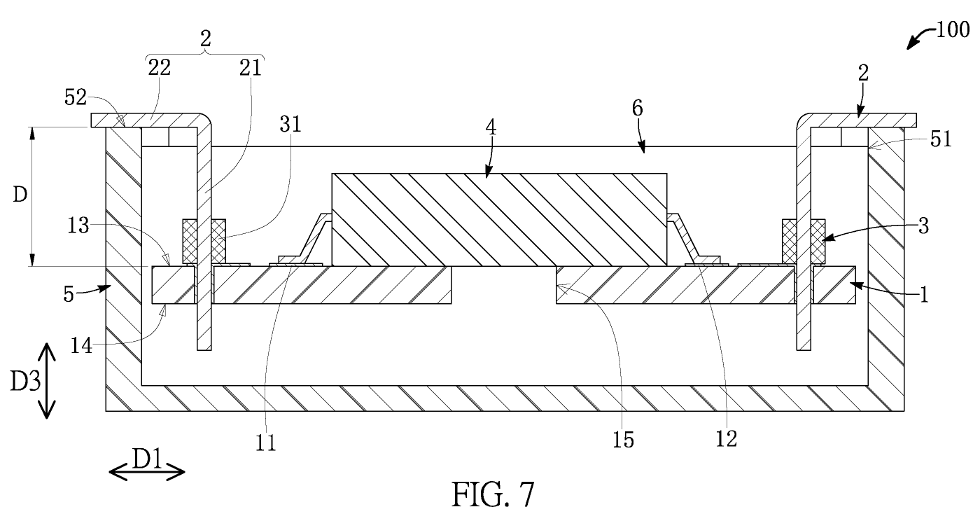

As shown in FIGS. 3 and 7, the pins 2 are inserted into the circuit board 1 and are respectively and electrically coupled to the two first metal pads 11 and the two second metal pads 12. In the present embodiment, the pins 2 are pre-bent and have substantially a same L-shaped structure, and each of the pins 2 has an insertion segment 21 and a bent segment 22 that is curvedly connected to the insertion segment 21, but the present disclosure is not limited thereto. For example, in other embodiments of the present disclosure not shown in the drawings, the pins 2 can have different structures from each other according to practical requirements.

Furthermore, the insertion segments 21 of the pins 2 are inserted into the circuit board 1, and the bent segment 22 of each of the pins 2 extends from the insertion segment 21 in a direction away from the circuit board 1. In order to effectively control a distance between the bent segments 22 of the pins 2 and the circuit board 1, the insertion segments 21 of the pins 2 in the present embodiment can be further inserted into the positioning structure 3 for allowing the pins 2 to abut against the circuit board 1 through the positioning structure 3, so that the bent segment 22 of each of the pins 2 and the circuit board 1 can be controlled to be spaced apart by a predetermined arrangement depth D. Accordingly, the bent segments 22 of the pins 2 can be arranged in a more accurate coplanar configuration.

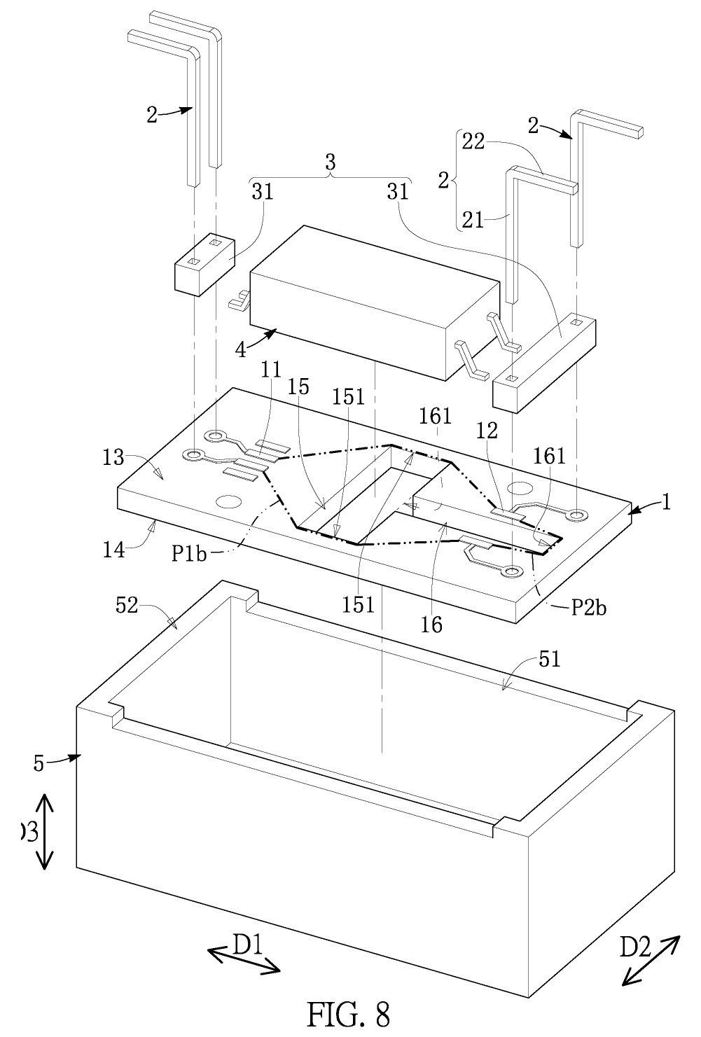

Specifically, the positioning structure 3 in the present embodiment includes a plurality of alignment insulators 31, and the insertion segments 21 of the pins 2 are respectively inserted into the alignment insulators 31. For example, as shown in FIG. 3, a quantity of the alignment insulators 31 can be four, and each of the pins 2 is inserted into one of the alignment insulators 31; or, as shown in FIG. 8, a quantity of the alignment insulators 31 can be two, and two of the pins 2 electrically coupled to the two first metal pads 11 are inserted into one of the alignment insulators 31, and two of the pins 2 electrically coupled to the two second metal pads 12 are inserted into another one of the alignment insulators 31.

As shown in FIGS. 3, 4 and 7, the electronic component 4 is assembled to the first board surface 13 or the second board surface 14 of the circuit board 1, and the electronic component 4 is electrically coupled to the two first metal pads 11 and the two second metal pads 12. The electronic component 4 can be replaced by a chip that is assembled and electrically coupled to the circuit board 1 in a flip-chip manner, but the present disclosure is not limited thereto. For example, in other embodiments of the present disclosure not shown in the drawings, the electronic component 4 can be replaced by several other semiconductor components or several passive components electrically coupled to the circuit board 1.

Specifically, the two first metal pads 11 are located at one side of the electronic component 4, the two second metal pads 12 are located at another side of the electronic component 4, and the electronic component 4 covers a portion of the first penetrating groove 15 and a portion of the second penetrating groove 16 along a thickness direction D3 that is perpendicular to the first direction D1 and the second direction D2. In the present embodiment, the electronic component 4 does not shield the two first groove ends 151 of the first penetrating groove 15 and the two second groove ends 161 of the second penetrating groove 16 along the thickness direction D3, but the present disclosure is not limited thereto.

The case 5 has a cavity, and a bottom side 52 of the case 5 defines an opening 51. The circuit board 1, the electronic component 4, the positioning structure 3, and a portion of each of the pins 2 pass through the opening 51 of the case 5 and are disposed in the case 5. The bent segments 22 of the pins 2 abut against the bottom side 52 of the case 5, so that the circuit board 1 and the components assembled thereon can be located at a predetermined depth of the case 5 (e.g., the circuit board 1 is located at the predetermined arrangement depth D; or, the bent segments 22 of the pins 2 abut against the circuit board 1 at the predetermined arrangement depth D).

Furthermore, the encapsulant 6 is filled in the case 5, and the circuit board 1, the electronic component 4, the positioning structure 3, and the portion of each of the pins 2 are embedded in the encapsulant 6. In the present embodiment, at least part of the insertion segment 21 of each of the pins 2 is embedded in the encapsulant 6, and the bent segment 22 of each of the pins 2 is exposed from the encapsulant 6 for providing the electronic device 100 to perform soldering operations.

Specifically, the material of the encapsulant 6 can be a high dielectric insulating gel (>20KV), such as epoxy with a dielectric strength greater than 24kV, or silicone with a dielectric strength greater than 30kV. The case 5 can be made of a high dielectric insulating gel that is high temperature resistant and has a dielectric strength greater than 30kV, such as polyamide engineering plastic (PA9T). In addition, the plastic or gel mentioned above will be added with dyes or black ink, preferably in dark colors (e.g., black or dark gray). Furthermore, in the selection of the case 5, the encapsulant 6, and the circuit board 1, the glass transition temperature (Tg), coefficient of thermal expansion (CTE), and tolerance to reflow soldering process (260 ℃) all undergo simulation and matching of physical properties, and three reflow soldering processes (peak of 260 ℃) and solderability verification are performed to comply with MSL level 1, as well as verification of the flame retardancy UL94 V-0.

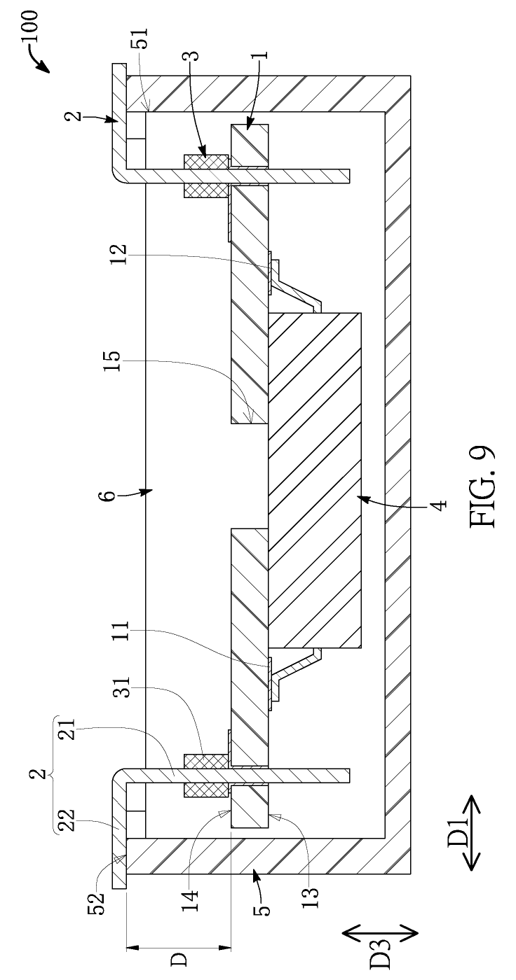

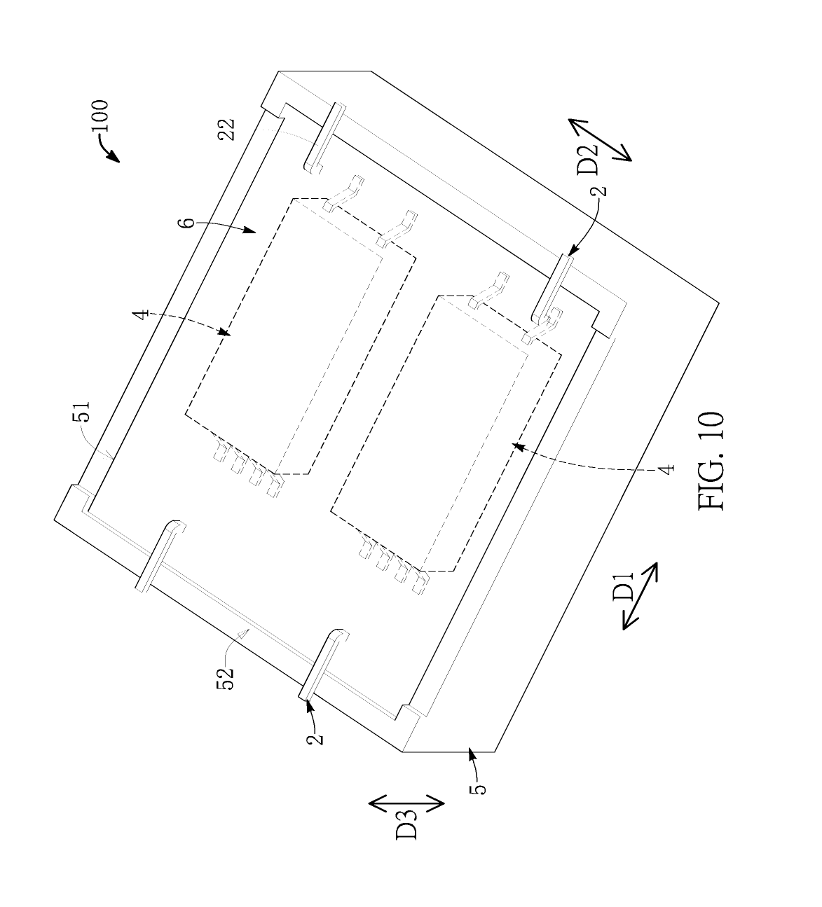

It should be noted that the electronic device 100 shown in FIG. 7 of the present embodiment is provided with one electronic component 4, and the electronic component 4 and the positioning structure 3 are disposed on the first board surface 13 of the circuit board 1, but the present disclosure is not limited thereto. For example, as shown in FIG. 9, the positioning structure 3 can be disposed on the second board surface 14 of the circuit board 1, and the electronic component 4 is disposed on the first board surface 13 of the circuit board 1; or, as shown in FIG. 10, the electronic device 100 can be provided with a plurality of electronic components 4 (e.g., two optocouplers) on the circuit board 1 according to practical requirements.

In addition, at least one of the first penetrating groove 15 and the second penetrating groove 16 provided by the present embodiment can be defined as a creepage-distance-extending structure that is configured to interrupt an electric field defined by at least one of the first initial creepage path P1a and the second initial creepage path P2a of the circuit board 1, but the present disclosure is not limited thereto. In other embodiments of the present disclosure not shown in the drawings, the creepage-distance-extending structure can be provided in another form other than grooves according to practical requirements.

### Second Embodiment

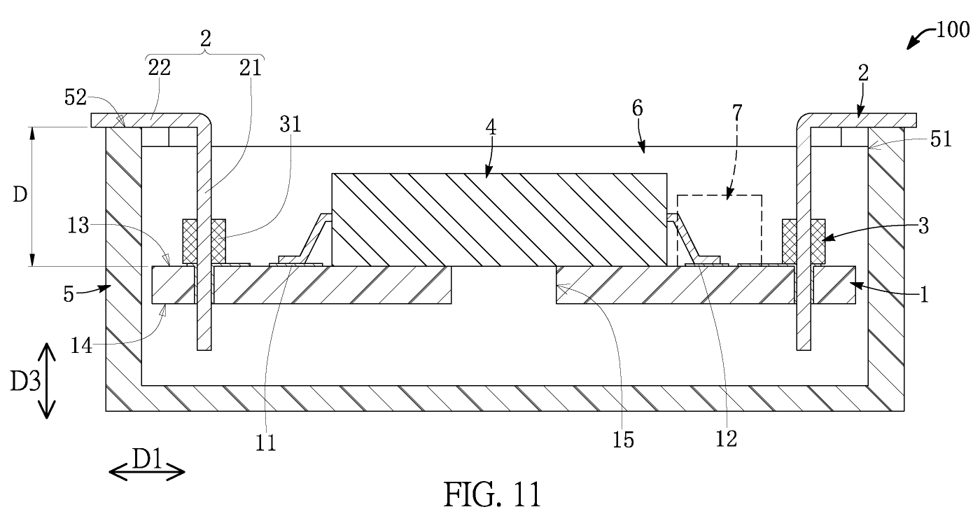

Referring to FIGS. 11 to 13, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, the electronic device 100 further includes a semiconductor component 7 embedded in the encapsulant 6. The semiconductor component 7 is disposed on the circuit board 1 and is spaced apart from the electronic component 4, and the semiconductor component 7 is electrically coupled to the electronic component 4 through the circuit board 1. Furthermore, the semiconductor component 7 can be a semiconductor chip having a flip-chip configuration and can be electrically coupled to the circuit board 1 in a wire bonding manner, but the present disclosure is not limited thereto.

In other words, the electronic device 100 of the present embodiment is provided with components that have different electrical characteristics and that are arranged therein to form a miniaturized module for supporting different application circuit functions. For example, each of the electronic component 4 and the semiconductor component 7 can be one of the following types: (1) high-power or high-voltage PhotoRelay types (e.g., PVG and MOS); (2) multiple components connected in series to superimpose electrical functions (e.g., two PhotoRelays connected in series to increase their withstand voltage); (3) application types such as SiC MOS drive modules combined with anti-noise circuits; or (4) optocoupler drive type and MOSFET.

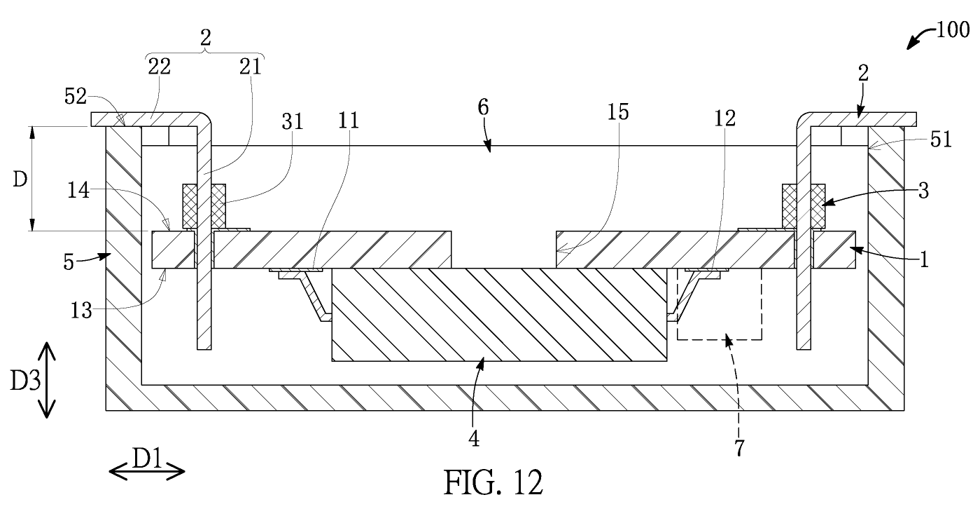

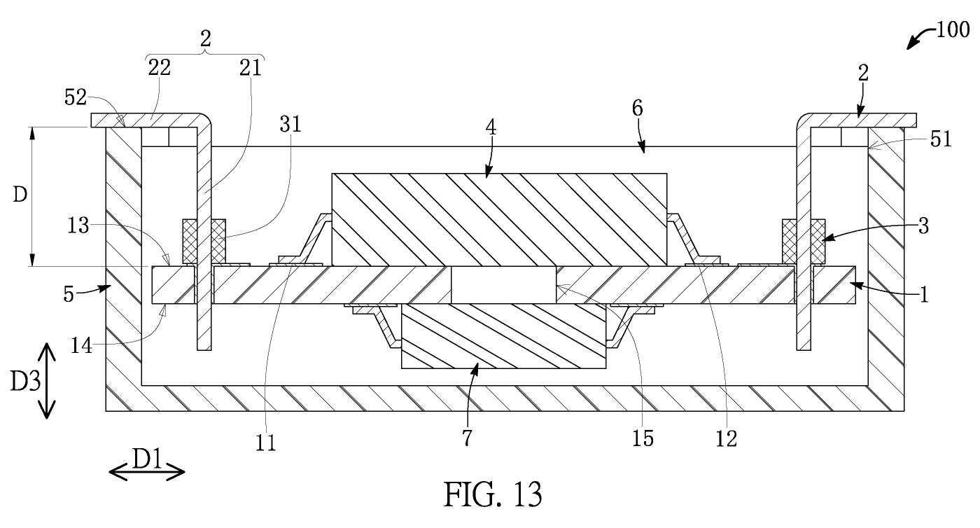

Specifically, the electronic component 4 and the semiconductor component 7 can be jointly disposed on one of the first board surface 13 and the second board surface 14 (e.g., FIGS. 11 and 12 according to practical requirements, or can be respectively disposed on the first board surface 13 and the second board surface 14 of the circuit board 1 (e.g., FIG. 13).

In addition, the type of the semiconductor component 7 can include at least one of a resistor, a capacitor, an inductor, a Zener diode, a protection component, and a bare die. The resistor can be a current limiting resistor or a metal oxide varistor (MOV), and the protection component can be a snubber circuit, but the present disclosure is not limited thereto.

### Beneficial Effects of the Embodiments

In conclusion, the circuit module, the circuit board, the electronic device, and the package module in the present disclosure can be provided by forming at least one creepage distance extending structure, such as the first penetrating groove and the second penetrating groove at specific positions on the circuit board for enabling the first initial creepage path to be effectively extended to the first extension creepage path, and the second initial creepage path to be effectively extended to the second extension creepage path, so that the circuit board (or the electronic device) can meet more stringent creepage distance requirements.

Specifically, the present disclosure provides an optocoupler-based high-voltage semiconductor relay module and an integrated design method thereof, which can greatly improve the electrical clearance and withstand voltage capability between the input terminal and the output terminal, and can further integrate the electronic component (e.g., optocoupler) and its peripheral application circuits into a single module to simultaneously meet the safety needs of high-voltage energy storage systems (e.g., IEC/EN 62477) and the needs of high-power density AI server power supplies for miniaturization, modularization, and high reliability.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A circuit module, comprising:
a circuit board including:
two first metal pads spaced apart from each other and disposed on one side of the circuit board;
two second metal pads spaced apart from each other and disposed on another side of the circuit board, wherein the two first metal pads respectively correspond to the two second metal pads, each of the two first metal pads and a corresponding one of the two second metal pads jointly define a first initial creepage path therebetween, and the two second metal pads jointly define a second initial creepage path therebetween;
a first penetrating groove passing through the two first initial creepage paths, wherein the two first metal pads are spaced apart from the two second metal pads along a first direction through the first penetrating groove; and
a second penetrating groove arranged between the two second metal pads, wherein one of the two second metal pads is spaced apart from another one of the two second metal pads along a second direction through the second penetrating groove;
wherein the first penetrating groove has two first groove ends, and each of the two first metal pads and the corresponding one of the two second metal pads jointly define a first extension creepage path at an adjacent one of the two first groove ends, and wherein a length of the first extension creepage path is within a range from 110% to 500% of the first initial creepage path;
wherein the second penetrating groove has two second groove ends, and the two second metal pads and an adjacent one of the two second groove ends jointly define a second extension creepage path, and wherein a length of the second extension creepage path is within a range from 130% to 500% of the second initial creepage path; and
a plurality of pins fixed to the circuit board and electrically coupled to the two first metal pads and the two second metal pads, respectively.

2. The circuit module according to claim 1, wherein one of the two second groove ends of the second penetrating groove is spaced apart from the first penetrating groove.

3. The circuit module according to claim 1, wherein one of the two second groove ends of the second penetrating groove is connected to the first penetrating groove.

4. The circuit module according to claim 1, wherein the second penetrating groove intersects with the first penetrating groove, and the two second groove ends are respectively located at two opposite sides of the first penetrating groove.

5. The circuit module according to claim 1, wherein each of the plurality of pins has an insertion segment and a bent segment that is curvedly connected to the insertion segment.

6. The circuit module according to claim 5, further comprising a positioning structure, wherein the insertion segments of the plurality of pins are inserted into the positioning structure, such that the bent segments abut against the circuit board at a predetermined arrangement depth.

7. The circuit module of claim 1, wherein the first penetrating groove has a length of at least 3 mm and a width of at least 1.5 mm.

8. The circuit module of claim 1, wherein the second penetrating groove has a length of at least 4 mm and a width of at least 2 mm.

9. The circuit module of claim 1, wherein an edge of the circuit board is spaced apart from one of the two first groove ends adjacent thereto by at least 1.5 mm and is spaced apart from one of the two second groove ends adjacent thereto by at least 1.5 mm.

10. The circuit module of claim 1, wherein the first penetrating groove corresponds to an insulation distance of at least 14.8 mm, and the second penetrating groove corresponds to an insulation distance of at least 14.8 mm and 15.4 mm.

11. A circuit board configured for an electronic device and comprising the structural features as claimed in claim 1.

12. The circuit board according to claim 11, wherein one of the two second groove ends of the second penetrating groove is spaced apart from the first penetrating groove.

13. The circuit board according to claim 11, wherein the second penetrating groove is connected to the first penetrating groove through one of the two second groove ends or intersects the first penetrating groove.

14. An electronic device, comprising:
the circuit module as claimed in claim 1;
an electronic component disposed on the circuit board and electrically coupled to the two first metal pads and the two second metal pads;
a case having a cavity with an opening that is arranged at a bottom side of the case, wherein the circuit board, the electronic component, and portions of the plurality of pins are disposed in the case; and
an encapsulant filled in the case to embed the circuit board, the electronic component, and the portions of the plurality of pins.

15. The electronic device according to claim 14, wherein each of the plurality of pins has an insertion segment and a bent segment that is curvedly connected to the insertion segment, wherein the bent segments of the plurality of pins abut against the bottom side of the case, and at least part of the insertion segment of each of the plurality of pins is embedded in the encapsulant.

16. The electronic device according to claim 14, further comprising a semiconductor component disposed on the circuit board and embedded in the encapsulant, wherein the semiconductor component is electrically coupled to the electronic component.

17. The electronic device according to claim 16, wherein the electronic component and the semiconductor component are respectively disposed on two opposite surfaces of the circuit board or are jointly disposed on a same surface of the circuit board.

18. A package module, comprising:
a case having a cavity with an opening that is arranged at a bottom side of the case;
an electronic component disposed in the case;
a plurality of pins each having an insertion segment and a bent segment, the bent segments of the plurality of pins abutting against the bottom side of the case; and
an encapsulant filled in the case to embed at least part of the insertion segments of the plurality of pins and the electronic component, wherein the bent segments of the plurality of pins are exposed from the encapsulant.

19. The package module according to claim 18, further comprising a circuit board defining an initial creepage path, wherein the electronic component is disposed on the circuit board, and wherein the circuit board comprises at least one creepage-distance-extending structure that is configured to interrupt an electric field defined by the initial creepage path of the circuit board.

20. The package module of claim 18, wherein the case is made of an insulating plastic having a dielectric strength greater than 30 kV, and the encapsulant comprises an epoxy having a dielectric strength greater than 24 kV or a silicone having a dielectric strength greater than 30 kV.
